(19) United States
(12) Patent Application Publication
(10) Pub. No.: US 2026/0293702 A1
(43) Pub. Date: Sep. 24, 2026

(54) SEMICONDUCTOR DEVICE AND METHOD FOR MANUFACTURING SEMICONDUCTOR DEVICE

(71) Applicant: KABUSHIKI KAISHA TOSHIBA, Kawasaki-shi (JP)

(72) Inventor: Taizo TOMIOKA, Yokohama Kanagawa (JP)

(73) Assignee: KABUSHIKI KAISHA TOSHIBA, Kawasaki-shi (JP)

(21) Appl. No.: 19/551,723

(22) Filed: Feb. 27, 2026

(30) Foreign Application Priority Data
Mar. 24, 2025 (JP) 2025-047975
Jan. 30, 2026 (JP) 2026-014308

(51) Int. Cl. H10W 70/40; H10W 70/04; H10W 74/01; H10W 74/10; H10W 90/00

(52) U.S. Cl. CPC H10W 70/411; H10W 70/041; H10W 70/048; H10W 70/481; H10W 74/016; H10W 74/111; H10W 90/756; H10W 90/766

(57) ABSTRACT

According to one embodiment, a semiconductor device includes a semiconductor element including a first electrode and a semiconductor chip, and a base including a first conductive member including a first bonding region. The first electrode is located between the first bonding region and the semiconductor chip in a first direction extending from the first bonding region toward the semiconductor chip. The first bonding region includes a first region and a first other region. The first region is located between the first other region and the first electrode in the first direction. The first region is in contact with the first electrode. A first mean diameter of first metal crystal grains included in the first region is smaller than a first other mean diameter of first other metal crystal grains included in the first other region.

### CROSS-REFERENCE TO RELATED APPLICATION

This application is based upon and claims the benefit of priority from Japanese Patent Application No. 2025-047975, filed on Mar. 24, 2025, and Japanese Patent Application No. 2026-014308, filed on Jan. 30, 2026; the entire contents of which are incorporated herein by reference.

### FIELD

Embodiments described herein relate generally to a semiconductor device and a method for manufacturing a semiconductor device.

### BACKGROUND

It is desirable for a semiconductor device in which a semiconductor chip is mounted to, for example, improve characteristics, such as a reduction in the thermal resistance between the semiconductor chip and the substrate.

### BRIEF DESCRIPTION OF THE DRAWINGS

FIG. 1 is a schematic cross-sectional view illustrating a semiconductor device according to a first embodiment;

FIG. 2 is a schematic cross-sectional view illustrating a second configuration of an electrode of a semiconductor chip of the semiconductor device according to the first embodiment;

FIG. 3 is a schematic cross-sectional view illustrating a semiconductor device according to a second embodiment;

FIG. 4 is a schematic cross-sectional view illustrating a semiconductor device according to a third embodiment;

FIGS. 5A to 5D are schematic diagrams illustrating a method for manufacturing the semiconductor device according to the first embodiment;

FIGS. 6A to 6D are schematic diagrams illustrating a method for manufacturing the semiconductor device according to the third embodiment;

FIG. 7 shows results of a bonding experiment;

FIG. 8 is a secondary electron image of a cross section of a bonding portion between a Si chip and a Cu frame fabricated in the bonding experiment;

FIG. 9 is a secondary electron image of the surface of a Cu frame after shear fracture of the bonding portion between the Si chip and the Cu frame fabricated in the bonding experiment;

FIG. 10 is a schematic cross-sectional view illustrating a semiconductor device according to a reference example;

FIG. 11 is a schematic cross-sectional view illustrating the semiconductor device according to the first embodiment;

FIG. 12 is a schematic cross-sectional view illustrating the semiconductor device according to the first embodiment;

FIG. 13 is an example image of the semiconductor device according to the first embodiment;

FIGS. 14A and 14B are example images of a part of the semiconductor device according to the first embodiment;

FIG. 15 is a schematic cross-sectional view illustrating a part of the semiconductor device according to the first embodiment;

FIG. 16 is a schematic cross-sectional view illustrating a part of the semiconductor device according to the first embodiment;

FIG. 17 is a schematic cross-sectional view illustrating a part of the semiconductor device according to the first embodiment;

FIG. 18 is a schematic cross-sectional view illustrating the semiconductor device according to the second embodiment;

FIG. 19 is a schematic cross-sectional view illustrating the semiconductor device according to the third embodiment;

FIG. 20 is a schematic cross-sectional view illustrating a part of the semiconductor device according to the third embodiment;

FIGS. 21A to 21D are schematic cross-sectional views illustrating a method for manufacturing a semiconductor device according to a fifth embodiment;

FIGS. 22A and 22B are schematic cross-sectional views illustrating the method for manufacturing the semiconductor device according to the fifth embodiment; and

FIG. 23 is a schematic cross-sectional view illustrating the method for manufacturing the semiconductor device according to the fifth embodiment.

### DETAILED DESCRIPTION

According to one embodiment, a semiconductor device includes a semiconductor element including a first electrode and a semiconductor chip, and a base including a first conductive member including a first bonding region. The first electrode is located between the first bonding region and the semiconductor chip in a first direction extending from the first bonding region toward the semiconductor chip. The first bonding region includes a first region and a first other region. The first region is located between the first other region and the first electrode in the first direction. The first region is in contact with the first electrode. A first mean diameter of first metal crystal grains included in the first region is smaller than a first other mean diameter of first other metal crystal grains included in the first other region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

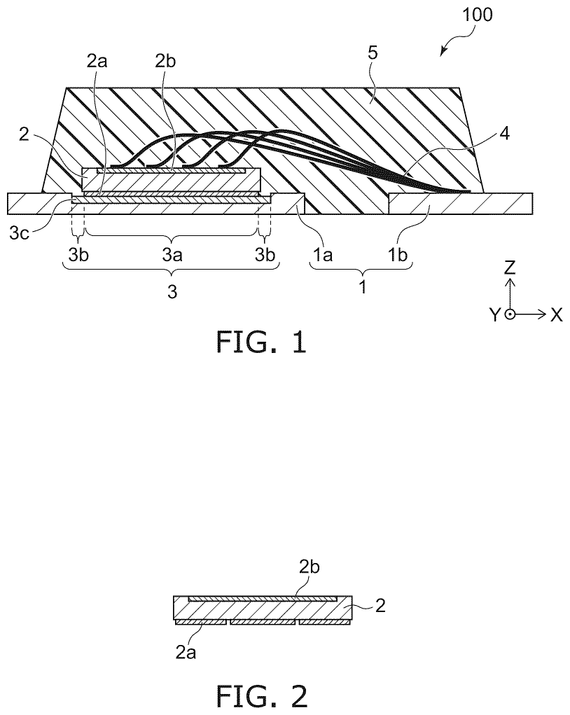

FIG. 1 is a schematic cross-sectional view illustrating a semiconductor device according to a first embodiment.

A semiconductor device 100 includes a base 1 and a semiconductor chip 2. The base 1 in this example is a lead frame. The lead frame includes a metal first conductive member 1a (first frame) and a metal second conductive member 1b (second frame). The thickness of each of the first conductive member 1a and the second conductive member 1b is, for example, 0.2 mm. The semiconductor chip 2 is, for example, a power semiconductor chip, such as an IGBT (Insulated Gate Bipolar Transistor) or a power MOSFET (Metal Oxide Semiconductor Field-Effect Transistor). The semiconductor chip 2 is provided with a first electrode 2a and a second electrode 2b. The first electrode 2a is provided on the bottom surface of the semiconductor chip 2. The second electrode 2b is provided on a face (top surface) opposite to the face on which the first electrode 2a is provided. The first electrode 2a is a metal film having a thickness of, for example, 10 μm. Between the first electrode 2a and the semiconductor chip 2, a Ti film (not illustrated) having a thickness of, for example, 20 nm may be provided. The second electrode 2b is a metal film having a thickness of, for example, 5 μm. The main element included in the first electrode 2a and the second electrode 2b is, for example, Cu or Al.

In this example, the first conductive member 1a includes a recessed portion 3. The semiconductor chip 2 is placed in the recessed portion 3. In the superficial layer of the bottom surface of the recessed portion 3, a first modified layer 3c in which crystal grains are refined is partially formed. The first electrode 2a and the first modified layer 3c are directly bonded to each other. The shape of the recessed portion 3 as viewed along a Z-direction may be, for example, a round shape or an oval shape. The area of the recessed portion 3 in an XY plane is larger than the area of the semiconductor chip 2 in the XY plane. In the recessed portion 3, a first bonding region 3a and a first non-bonding region 3b are present. The first bonding region 3a is bonded to the first electrode 2a of the semiconductor chip 2. The first non-bonding region 3b is not bonded to the first electrode 2a of the semiconductor chip 2. The first non-bonding region 3b is located outside the first bonding region 3a. On the surface of the first non-bonding region 3b, arc-shaped streaks caused by the manufacturing method may remain. The surface roughness of the first non-bonding region 3b is different from the surface roughness of a portion (non-recessed portion 3p) of the first conductive member 1a other than the recessed portion 3. Between the bottom surface of the recessed portion 3 and the first conductive member 1a (non-recessed portion 3p), a step of, for example, 30 μm in the Z-direction is provided. In the first conductive member 1a, the mean diameter of the metal crystal grains in the first modified layer 3c is, for example, 5 μm. The mean diameter of the metal crystal grains in a portion of the first conductive member 1a other than the first modified layer 3c is, for example, 100 μm. The second electrode 2b and the second conductive member 1b are connected by a metal wire 4 having a diameter of, for example, 0.3 mm. The semiconductor chip 2, a part of the first conductive member 1a, a part of the second conductive member 1b, and the wire 4 are sealed with a resin 5. The main element included in the outermost surface layer of the first electrode 2a and that included in the first conductive member 1a are the same. The main element included in the first electrode 2a, the second electrode 2b, the first conductive member 1a, the second conductive member 1b, and the wire 4 may be Cu or Al. The composition ratio of the element in a first bonding portion 35 between the first electrode 2a and the first conductive member 1a is 95 mass % or more. The first bonding portion 35 may include another element, such as Au, Ag, or Fe. The composition ratio of the other element in the first bonding 30 portion 35 is less than 5 mass %.

FIG. 2 is a schematic cross-sectional view illustrating a second configuration of the electrode of the semiconductor chip of the semiconductor device according to the first embodiment.

The first electrode 2a of the semiconductor chip 2 may be constituted by a plurality of divided electrodes. When the first electrode 2a is divided, thermal stress caused by a difference in the coefficient of thermal expansion between the semiconductor chip 2 and the first conductive member 1a is relaxed. Damage to the semiconductor chip 2 and damage to the bonding portion between the first electrode 2a and the first modified layer 3c can be prevented.

### Second Embodiment

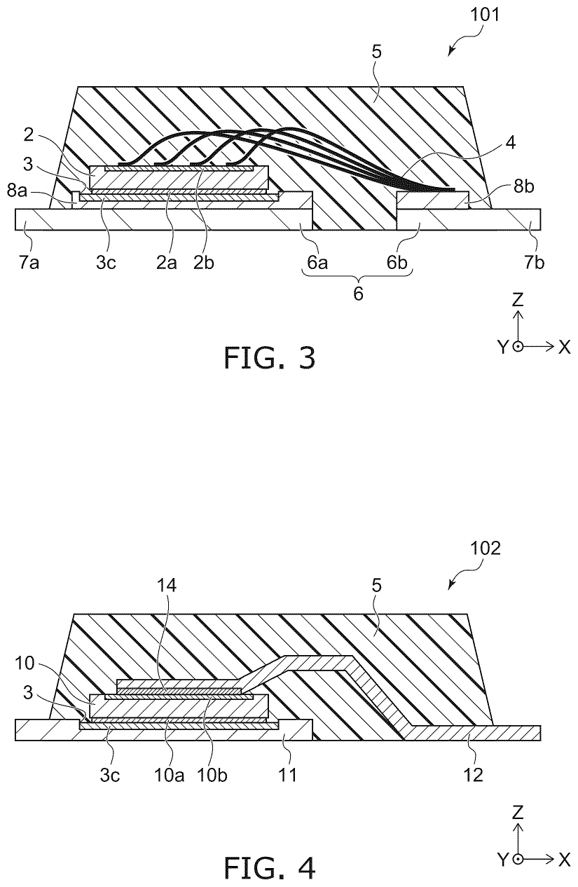

FIG. 3 is a schematic cross-sectional view illustrating a semiconductor device according to a second embodiment.

A semiconductor device 101 includes the semiconductor chip 2, a base 6, the resin 5, and the wire 4. The base 6 includes a first conductive member 6a and a second conductive member 6b. The semiconductor chip 2 includes the first electrode 2a including Al as the main element and the second electrode 2b including Al as the main element.

The first conductive member 6a includes a Cu portion 7a including Cu as the main element and an Al portion 8a including Al as the main element. The second conductive member 6b includes a Cu portion 7b and an Al portion 8b. The area of the Al portion 8a exceeds the area of the semiconductor chip 2 in the XY plane. The Al portion 8a includes the recessed portion 3 having a depth of 30 μm. In the bottom portion of the recessed portion 3, the first modified layer 3c is formed. The shape of the recessed portion 3 as viewed along the Z-direction is a round shape or an oval shape. The first electrode 2a of the semiconductor chip 2 and the first modified layer 3c of the first conductive member 6a are directly bonded to each other. The surface of the first modified layer 3c includes a portion other than the region bonded to the first electrode 2a. This portion has arc-shaped grooves. The second electrode 2b is connected to the Al portion 8b of the second conductive member 6b by the wire 4. The mean diameter of the crystal grains in the first modified layer 3c of the Al portion 8a is, for example, 3 μm. The mean diameter of the crystal grains in a portion of the Al portion 8a other than the first modified layer 3c is 30 μm. The mean diameter of the crystal grains in the first modified layer 3c is smaller than the mean diameter of the crystal grains in the portion other than the first modified layer 3c. The configuration of the rest may be the same as that of the semiconductor device 100.

The main element of the first electrode 2a, the second electrode 2b, and the first modified layer 3c in the bottom portion of the recessed portion 3 of the first conductive member 6a is Al. The first electrode 2a, the second electrode 2b, and the first modified layer 3c may include another element, such as Au, Ag, or Fe. The composition ratio of the other element in the first electrode 2a, the second electrode 2b, and the first modified layer 3c is less than 5 mass %. The base 6 may be formed of, for example, a Cu—Al clad material. For example, the base 6 may be formed by processing the Cu—Al clad material by a method of at least either cutting or etching.

### Third Embodiment

FIG. 4 is a schematic cross-sectional view illustrating a semiconductor device according to a third embodiment.

A semiconductor device 102 according to the third embodiment includes a semiconductor chip 10, the base 1, and the resin 5. The base 1 includes a first conductive member 11 and a second conductive member 12. The first conductive member 11 corresponds to the first conductive member 1a shown in FIG. 1. The semiconductor chip 10 is provided with a first electrode 10a and a second electrode 10b. The first conductive member 11 includes the recessed portion 3. The semiconductor chip 10 is placed in the recessed portion 3. The depth of the recessed portion 3 is, for example, 30 μm. The shape of the recessed portion 3 as viewed along the Z-direction is a round shape or an oval shape. At the bottom surface of the recessed portion 3, the first modified layer 3c including crystal grains having a mean diameter smaller than that in the surrounding portion is formed. The second conductive member 12 is, for example, a frame. On a face of an end portion of the second conductive member 12 facing the semiconductor chip 10, a second modified layer 14 is present. The mean diameter of the metal crystal grains in the second modified layer 14 is smaller than the mean diameter of the metal crystal grains in the second conductive member 12. The first electrode 10a of the semiconductor chip 10 is directly bonded to the first modified layer 3c of the first conductive member 11. The second electrode 10b is directly bonded to the second modified layer 14 of the second conductive member 12. The surface of the first modified layer 3c in a region other than the region bonded to the first electrode 10a has arc-shaped grooves. The surface roughness in this region is different from the surface roughness on the top surface of the first conductive member 11. The main element in the first electrode 10a and that in the first modified layer 3c are the same. The main element in the second electrode 10b and that in the second conductive member 12 are the same. The main element may be, for example, Cu or Al. In each case, another element, such as Au, Ag, or Fe may be included in a ratio of less than 5 mass %. The configuration of the rest may be the same as that of the semiconductor device 100.

FIG. 1, FIG. 3, and FIG. 4 illustrate semiconductor devices in which the base 1 or the base 6 called a lead frame formed of a metal plate is used. The base 1 and the base 6 may be ceramic substrates. The ceramic substrate is made of ceramic as a base material and includes the electrode in which the recessed portion 3 is formed. The base 1 and the base 6 may be resin substrates. The resin substrate is made of glass cloth and a resin as base materials and includes the electrode in which the recessed portion 3 is formed. The embodiments include a configuration in which the first electrode 2a of the semiconductor chip 2 and the semiconductor chip 10 is bonded to the single metal plate.

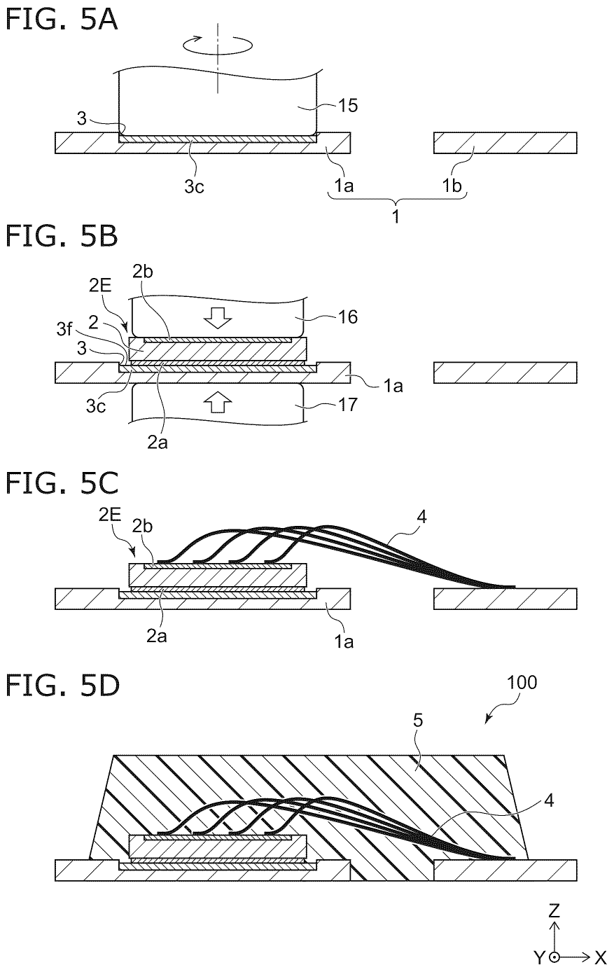

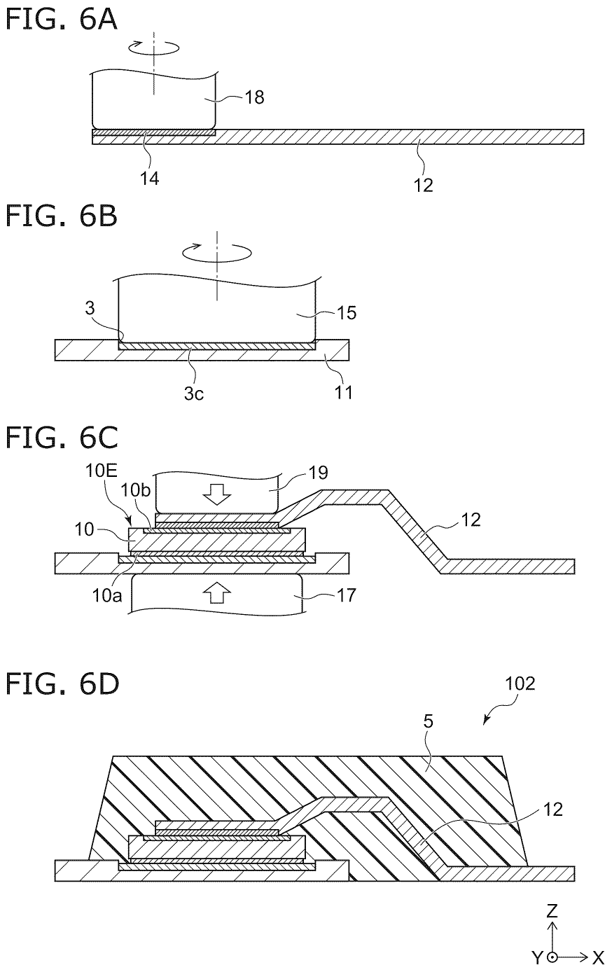

FIGS. 5A to 5D are schematic diagrams illustrating a method for manufacturing the semiconductor device according to the first embodiment.

First, the first conductive member 1a constituting the base 1 is pressurized for, for example, 3 seconds with a columnar friction stir processing tool 15 rotating at a rotation speed of, for example, 800 rpm. This processing method is called a friction stir processing. As a result of this processing, the recessed portion 3 including the first modified layer 3c in the bottom portion is formed in the first conductive member 1a (FIG. 5A). The metal crystal grains in the first conductive member 1a are refined by shear force applied by the rotation of the friction stir processing tool 15. The first modified layer 3c including crystal grains having a mean diameter of about 1 μm is formed. The mean diameter of the crystal grains before the processing is 100 μm. On the surface and its vicinity of the first modified layer 3c, a tensile stress of, for example, about 15 MPa remains. A similar crystal structure may be formed by cutting using a tool, such as an end mill, provided with a bottom cutting edge. When the cutting is performed by dry cutting without using a cutting oil, a modified layer in which a higher tensile stress remains is formed. The tensile stress remains in the first modified layer 3c before bonding of the first electrode 2a and the bottom surface of the recessed portion 3 to each other. The shape of the recessed portion 3 as viewed from the Z-direction, made by the friction stir processing and the cutting is a round shape or an oval shape. On the surface of the recessed portion 3, arc-shaped streaks remain.

The semiconductor chip 2 is provided with the first electrode 2a and the second electrode 2b. The first electrode 2a is formed by, for example, electrolytic Cu plating in a sulfuric acid bath, on a seed layer formed on an adhesion layer on the surface of Si. The adhesion layer is a Ti film formed by, for example, sputtering. The surface of the first electrode 2a formed by the Cu plating is planarized by machining using, for example, a diamond blade. Tensile stress remains on the Cu plated film formed in the sulfuric acid bath, and tensile stress is further applied by subsequent precision cutting. The second electrode 2b is formed by, for example, vapor deposition of Al. The semiconductor chip 2 is placed in the recessed portion 3 so that the first electrode 2a is in contact with the bottom surface of the recessed portion 3. The semiconductor chip 2 and the first conductive member 1a are pressurized and heated with an upper heating tool 16 and a lower heating tool 17, thereby bonding the first electrode 2a and the first modified layer 3c in the recessed portion 3 of the first conductive member 1a (FIG. 5B). The bonding temperature is, for example, 300° C. The pressurizing load is, for example, 15 MPa. The bonding time is, for example, 3 minutes. The temperature of the lower heating tool 17 before the pressurizing may be set to a temperature of not more than the recrystallization temperature of the metal forming the first conductive member 1a and the first electrode 2a. After the start of the pressurizing, the temperature of the lower heating tool 17 may be increased to the bonding temperature. In a case where the main element of the first conductive member 1a and the first electrode 2a is Cu, the bonding is performed in a nitrogen atmosphere, a reducing gas atmosphere, or under reduced pressure (under vacuum). In a case where the main element is Al, the bonding may be performed in the atmosphere.

Next, by ultrasonic bonding, the metal wire 4 is bonded to the second electrode 2b of the semiconductor chip 2, and the metal wire 4 is bonded to the second conductive member 1b (FIG. 5C).

With the resin 5, which is, for example, an epoxy resin containing a SiO₂ filler, the base 1, the semiconductor chip 2, and the wire 4 of, for example, Al are sealed (FIG. 5D).

FIGS. 6A to 6D are schematic diagrams illustrating a method for manufacturing the semiconductor device according to the third embodiment.

First, the second conductive member 12 is pressurized for, for example, 3 seconds with a small-diameter friction stir processing tool 18 rotating at a rotation speed of, for example, 800 rpm, thereby forming the second modified layer 14 (FIG. 6A). The second modified layer 14 will be bonded to the second electrode 10b.

Next, the first conductive member 11 is pressurized for, for example, 3 seconds with the friction stir processing tool 15 rotating at a rotation speed of, for example, 800 rpm, thereby forming the recessed portion 3 (FIG. 6B). At the bottom surface of the recessed portion 3, the first modified layer 3c is provided.

Next, the semiconductor chip 10 is placed in the recessed portion 3 of the first conductive member 11. The semiconductor chip 10 is provided with the first electrode 10a and the second electrode 10b. The surface of each of the first electrode 10a and the second electrode 10b has been planarized by machining. A modified layer may be formed on a surface of an end portion of the second conductive member 12. The second conductive member 12 is bent, and thereafter, is turned upside down. A part of the second conductive member 12 is overlaid on the second electrode 10b so that the second modified layer 14 faces the second electrode 10b. The first conductive member 11, the semiconductor chip 10, and the second conductive member 12 thus stacked are pressurized and heated with an upper small heating tool 19 and the lower heating tool 17. The first modified layer 3c of the first conductive member 11 and the first electrode 10a of the semiconductor chip 10 are bonded to each other, and the second modified layer 14 of the second conductive member 12 and the second electrode 10b of the semiconductor chip 10 are bonded to each other (FIG. 6C).

Last, the whole is sealed with the resin 5 to complete the semiconductor device 102 (FIG. 6D).

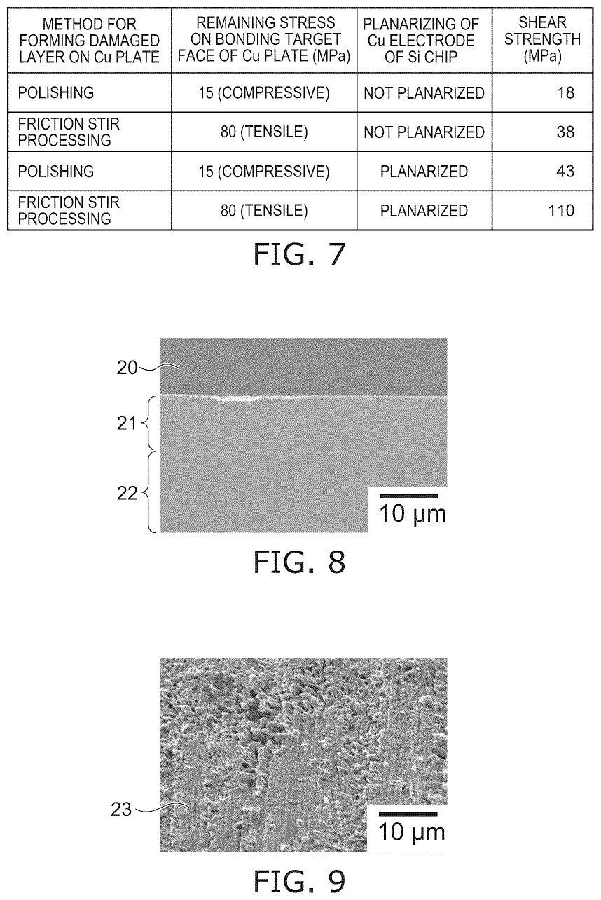

FIG. 7 shows results of a bonding experiment.

FIG. 8 is a secondary electron image of a cross section of a bonding portion between a Si chip and a Cu frame fabricated in the bonding experiment.

FIG. 9 is a secondary electron image of the surface of a Cu frame after shear fracture of the bonding portion between the Si chip and the Cu frame fabricated in the bonding experiment.

The bonding mechanism according to this example will be described below. Patent Documents 1, 2, and 3 disclose reference examples of a bonding technique in which, in a metal-to-metal solid-state bonding method, strain is applied in advance to bonding target faces. For example, strain is applied to a Ni-base alloy by polishing with emery paper or cold forging. That is, a modified layer in which compressive stress remains is formed on the bonding target faces. In the case of cold forging, the crystal grain diameter decreases from 1,330 μm to 340 μm. When the faces to which strain has been applied are brought into contact with each other, are heated up to 900° C., and are held for 10 to 15 minutes, recrystallization occurs in the crystal grains in the vicinity of the bonding target faces, and the faces are bonded.

Patent Document 4 discloses a method of thinning a modified layer on a surface, which is regarded as inhibiting bonding, by, for example, etching.

The inventor investigated the effect of the crystal grain diameter and residual stress on bonding target faces, on the bonding strength by performing a bonding experiment. In the experiment, a Si chip of 3×3 (mm²) including a Cu electrode 21, and a Cu frame 22 made of oxygen-free Cu are used. The thickness of the Cu electrode 21 is about 10 μm. As a result of the experiment, it was discovered that the bonding strength was low in a case where compressive stress remained on the bonding target faces and the bonding strength was high in a case where tensile stress remained, as shown in FIG. 7, and that a modified layer in which the tensile stress remained was effective for increasing the bonding strength. Further, it was found that the bonding strength was further increased by planarizing the Cu electrode 21 of the Si chip by machining, which led to the embodiments. The main bonding mechanism in this bonding is considered not to be recrystallization as indicated in Patent Documents 1, 2, and 3, but to be crystal growth in which adjacent refined crystals coalesce. FIG. 8 is a secondary electron image of a cross section of the bonding portion (first bonding portion) between the Si chip and the Cu frame 22 fabricated in the bonding experiment. It was found that the Cu electrode 21 of a Si chip 20, and the Cu frame 22 were bonded without any gap. FIG. 9 is a secondary electron image of the surface of the Cu frame 22 after the bonding portion between the Si chip and the Cu frame 22 fabricated in the bonding experiment was fractured by a shear test. This is a ductile fracture surface in which fine irregularities 23, which are traces of plastic deformation occurring during the shearing, are formed throughout the surface, which is considered to show good bonding.

The heat dissipation performance of the bonding portion obtained in this bonding experiment will be described below. A shear strength calculated from a value of 230 MPa to 255 MPa, which is the tensile strength of oxygen-free Cu available in the marketplace, is about 133 MPa to 147 MPa. The shear strength of a combination of the Cu frame 22 subjected to the friction stir processing and the planarized Cu electrode 21 is 110 MPa, and the bonding efficiency is determined to be 75% to 83%. The thermal conductivity of Cu is 391 W/m·K. Accordingly, the Cu bonding portion has a thermal conductivity of 292 W/m·K to 324 W/m·K, and is presumed to have a high heat dissipation performance exceeding that of a Ag sinter bonding portion.

When a semiconductor device operated, is a semiconductor chip included therein generates heat. When the temperature of the semiconductor chip rises due to this heat, power consumption increases, and malfunction occurs when the temperature exceeds a certain temperature. Therefore, the capability to externally dissipate the heat generated at the semiconductor chip affects the performance of the semiconductor device.

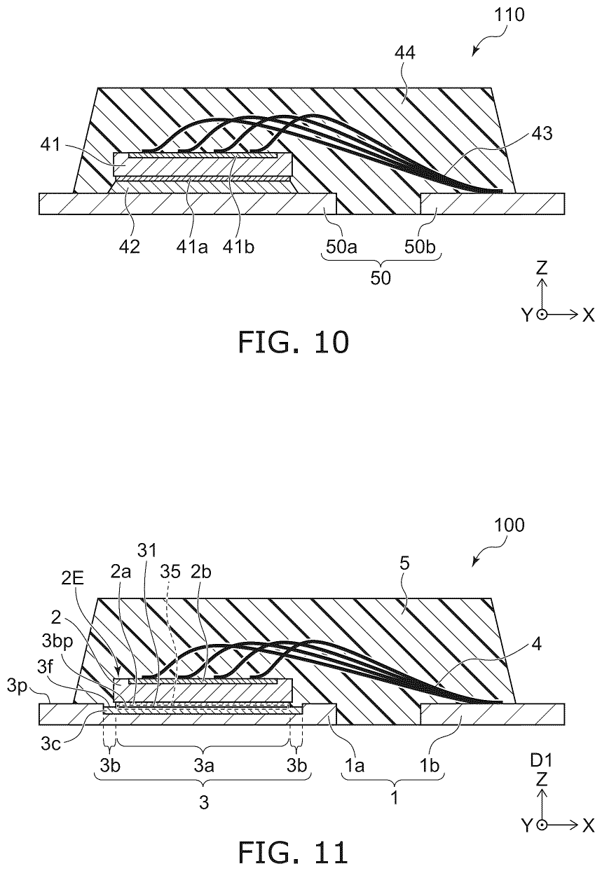

FIG. 10 is a schematic cross-sectional view illustrating a semiconductor device according to a reference example.

FIG. 10 is a schematic cross-sectional view showing, as an example semiconductor device, a semiconductor device 110 used in switching of an electric circuit. The semiconductor device 110 is constituted by a lead frame substrate 50 constituted by a frame 50a and an other frame 50b, a semiconductor chip 41 provided with a bottom electrode 41a and a top electrode 41b, a bonding body 42 bonding the bottom electrode 41a and the frame 50a to each other, a metal wire 43 connecting the top electrode 41b and the other frame 50b, and a resin 44. The bonding body 42 is formed of, for example, solder or a sintered body of fine Ag particles. In the configuration of the semiconductor device 110, heat generated in the semiconductor chip 41 is transmitted to the lead frame substrate 50 through the bonding body 42 and dissipated to the outside of the semiconductor device 110. Therefore, the thermal resistance of the bonding body 42 affects the performance of the semiconductor device 110, and the efficiency of the semiconductor device 110 is increased by reducing the thermal resistance. The performance of semiconductor chips has been increasing year by year, and development of a technique for attaining decreased thermal resistance has been desired. Embodiments described herein provide a highly efficient semiconductor device capable of, for example, reducing the thermal resistance between the semiconductor chip and the substrate, promptly dissipating the heat of the semiconductor chip to the outside, and decreasing heat loss.

FIG. 11 is a schematic cross-sectional view illustrating the semiconductor device according to the first embodiment.

As shown in FIG. 11, the semiconductor device 100 (see FIG. 1) includes a semiconductor element 2E and the base 1. The semiconductor element 2E includes the first electrode 2a and the semiconductor chip 2. In this example, the semiconductor element 2E further includes the second electrode 2b. At least a part of the semiconductor chip 2 is located between the first electrode 2a and the second electrode 2b.

The base 1 includes the first conductive member 1a. The first conductive member 1a includes the first bonding region 3a. A first direction D1 extending from the first bonding region 3a toward the semiconductor chip 2 is along the Z-direction. The first electrode 2a is located between the first bonding region 3a and the semiconductor chip 2 in the first direction D1. In this example, the first conductive member 1a includes the recessed portion 3. The semiconductor element 2E is placed on a bottom surface 3f of the recessed portion 3. At the bottom surface 3f, the first modified layer 3c is provided.

The first bonding region 3a included in the first conductive member 1a and the first electrode 2a are directly bonded to each other. An interface 31 between the first bonding region 3a and the first electrode 2a includes an element included in the first bonding region 3a and the first electrode 2a. The interface 31 does not substantially include an element not included in the first bonding region 3a and the first electrode 2a. The interface 31 may include an element not included in the first bonding region 3a and the first electrode 2a as an impurity.

As shown in FIG. 11, the first bonding portion 35 includes the interface 31 between the first bonding region 3a and the first electrode 2a. The first bonding portion 35 may include a part of the first bonding region 3a and a part of the first electrode 2a. The first bonding portion 35 includes an element included in the first bonding region 3a and the first electrode 2a, and does not substantially include an element not included in the first bonding region 3a and the first electrode 2a.

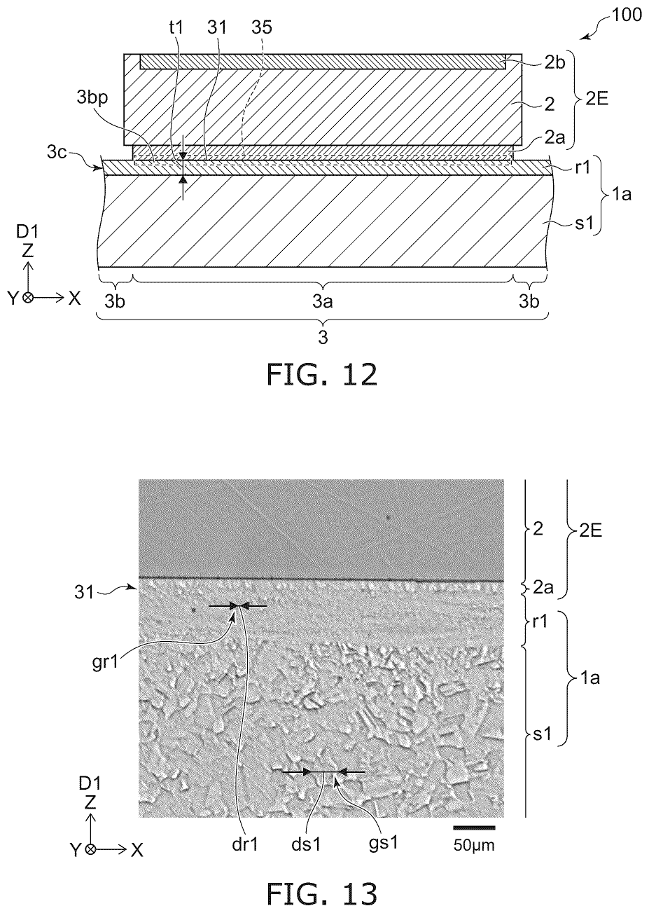

FIG. 12 is a schematic cross-sectional view illustrating the semiconductor device according to the first embodiment.

In FIG. 12, the resin 5 is omitted. As shown in FIG. 12, in the semiconductor device 100, the first bonding portion 35 may include the interface 31 between the first bonding region 3a and the first electrode 2a, a part of the first bonding region 3a, and a part of the first electrode 2a.

For example, the first bonding region 3a includes a first metal element. The first bonding region 3a includes the first metal element and does not substantially include another metal element. In a case where the first bonding region 3a includes the first metal element and another metal element, the composition ratio of the first metal element in the first bonding region 3a is not lower than the composition ratio of the other metal element in the first bonding region 3a. In a case where the first bonding region 3a includes the first metal element and a plurality of types of other metal elements, the composition ratio of the first metal element in the first bonding region 3a is not lower than the composition ratio of each of the plurality of types of other metal elements in the first bonding region 3a.

For example, the first electrode 2a includes the first metal element. The first electrode 2a includes the first metal element and does not substantially include another metal element. In a case where the first electrode 2a includes the first metal element and another metal element, the composition ratio of the first metal element in the first electrode 2a is not lower than the composition ratio of the other metal element in the first electrode 2a. In a case where the first electrode 2a includes the first metal element and a plurality of types of other metal elements, the composition ratio of the first metal element in the first electrode 2a is not lower than the composition ratio of each of the plurality of types of other metal elements in the first electrode 2a.

The first bonding portion 35 includes the first metal element. The composition ratio of the first metal element in the first bonding portion 35 may be 99.99 mass % or more. In a case where the first bonding portion 35 includes another element (first element), the composition ratio of the first metal element to the sum (whole) of the first metal element and the first element in the first bonding portion 35 is 95 mass % or more. The composition ratio of the first element to the all of the metal elements in the first bonding portion 35 is less than 5 mass %.

The first element includes, for example, at least one selected from the group consisting of Cu and Al. The other metal element described above includes, for example, at least one selected from the group consisting of Au, Ag, Mg, Si, and Fe.

As shown in FIG. 12, in the semiconductor device 100, the first bonding region 3a of the first conductive member 1a includes a first region r1 and a first other region s1. The first region r1 is located between the first other region s1 and the first electrode 2a in the first direction D1. The first region r1 is in contact with the first electrode 2a. The first region r1 corresponds to the first modified layer 3c described above. The first other region s1 corresponds to a portion other than the first modified layer 3c. The mean diameter of the metal crystal grains in the first modified layer 3c (first region r1) is smaller than the mean diameter of the metal crystal grains in the portion (first other region s1) other than the first modified layer 3c, as described above.

A first thickness t1 of the first region r1 along the first direction D1 is, for example, more than 0.2 μm and not more than 500 μm.

FIG. 13 is an example image of the semiconductor device according to the first embodiment.

FIG. 13 is an optical microscope image of a cross section of the first bonding portion 35. FIG. 13 is an example image showing the first conductive member 1a (first bonding region 3a), the first electrode 2a, and the interface 31 therebetween. In this example, each of the first conductive member 1a (first bonding region 3a) and the first electrode 2a is made of Cu. As shown in FIG. 13, the first region r1 is located between the first other region s1 and the first electrode 2a in the first direction D1. Each of the first region r1 and the first other region s1 includes metal crystal grains. The first region r1 includes first metal crystal grains gr1. The first other region s1 includes first other metal crystal grains gs1. A first mean diameter dr1 of the first metal crystal grains gr1 is smaller than a first other mean diameter ds1 of the first other metal crystal grains gs1.

With such a configuration, a high bonding strength (for example, shear strength) is obtained, as in the example experiment described above.

For example, in one example, the first mean diameter dr1 is about 1 μm and the first other mean diameter ds1 is about 50 μm, as described with reference to FIG. 1.

In the embodiment, for example, the first mean diameter dr1 is 0.02 times the first other mean diameter ds1. The first mean diameter dr1 may be not more than 0.2 times the first other mean diameter ds1.

For example, the first mean diameter dr1 may be not less than 0.05 μm and not more than 5 μm. The first other mean diameter ds1 may be not less than 10 μm and not more than 500 μm. A high bonding strength is obtained.

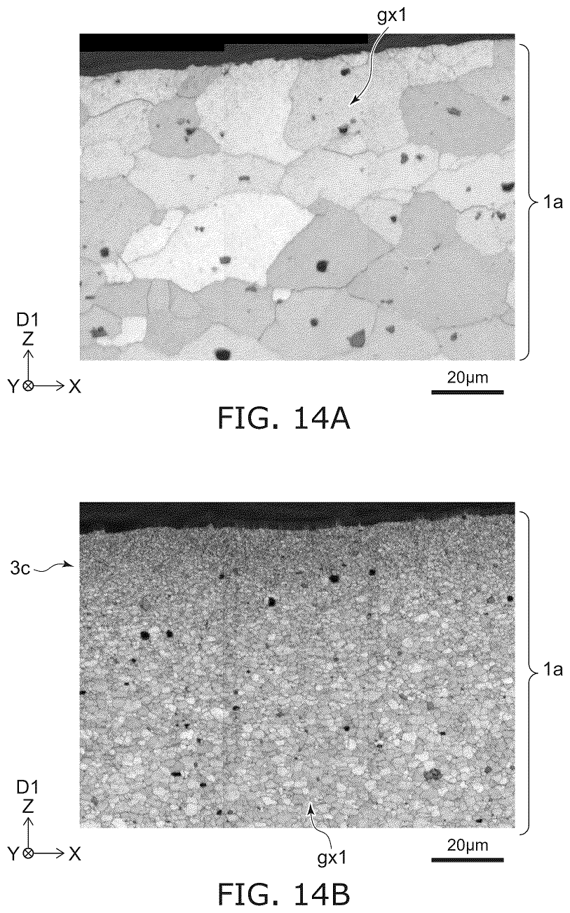

FIGS. 14A and 14B are example images of a part of the semiconductor device according to the first embodiment.

FIGS. 14A and 14B are Image quality maps constructed from EBSD (Electron Backscatter Diffraction) data of the first conductive member 1a before the first electrode 2a is bonded to the first conductive member 1a. FIG. 14A corresponds to the first conductive member 1a before the friction stir processing. FIG. 14B corresponds to the first conductive member 1a after the friction stir processing. In these samples, the first conductive member 1a is made of Al.

As shown in FIGS. 14A and 14B, metal crystal grains are refined by friction stir processing. The diameter of metal crystal grains gx2 after the friction stir processing are smaller than the diameter of the metal crystal grain gx1. In particular, the metal crystal grains gx3 that are near the surface of the modified layer 3c become finer crystal grains of 1 μm or less.

As shown in FIGS. 14A and 14B, the diameters of metal crystal grains gx1 (Al crystal grains) after the friction stir processing become smaller than the diameters of the metal crystal grains gx1 before the friction stir processing. For example, in the first modified layer 3c corresponding to the first region r1, the diameters of the metal crystal grains gx1 are obviously small.

In the embodiment, the first mean diameter dr1 of the first metal crystal grains gr1 in the first region r1 after bonding may be larger than that of the metal crystal grains gx1 in at least a part of the first modified layer 3c before the bonding. For example, the diameters of the metal crystal grains gx1 before the bonding may be increased by the bonding process.

In the embodiment, the first conductive member 1a may include a Cu layer and an Al layer. The Cu layer is stacked with the Al layer. The first conductive member 1a may be formed of, for example, a clad material.

As described above with reference to FIG. 1, the first conductive member 1a may include the recessed portion 3.

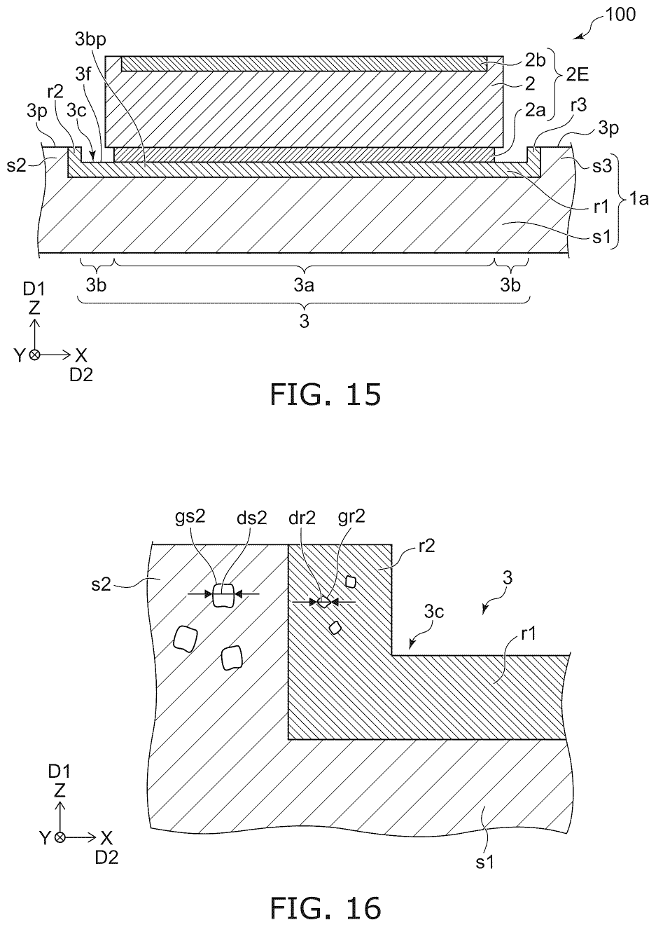

FIG. 15 is a schematic cross-sectional view illustrating a part of the semiconductor device according to the first embodiment.

FIG. 15 corresponds to a cross-sectional view taken when the semiconductor device 100 is cut along an X-Z plane (one plane including the first direction D1). In FIG. 15, the resin 5 is omitted. As shown in FIG. 15, when the first conductive member 1a is cut along one plane including the first direction D1, the first conductive member 1a includes the recessed portion 3 and a plurality of non-recessed portions 3p. The position (third position) of the recessed portion 3 in a second direction D2 crossing the first direction D1 is between the position (first position) of one of the plurality of non-recessed portions 3p in the second direction D2 and the position (second position) of another one of the plurality of non-recessed portions 3p in the second direction D2. At least a part of the first bonding region 3a is provided in the recessed portion 3. The second direction D2 may be any direction crossing the first direction D1 (Z-direction). One of the plurality of non-recessed portions 3p may be continuous with another one of the plurality of non-recessed portions 3p.

As shown in FIG. 15, the first conductive member 1a may include a second region r2 and a second other region s2. In the second direction D2, the second region r2 is located between the second other region s2 and at least a part of the first electrode 2a. The first conductive member 1a may further include a third region r3 and a third other region s3. In the second direction D2, the third region r3 is located between at least a part of the first electrode 2a and the third other region s3.

The second region r2 is continuous with the first region r1. The third region r3 is continuous with the first region r1. The second other region s2 is continuous with the first other region s1. The third other region s3 is continuous with the first other region s1. The second region r2 and the second other region s2 may be a part of the non-recessed portion 3p. The third region r3 and the third other region s3 may be another part of the non-recessed portion 3p.

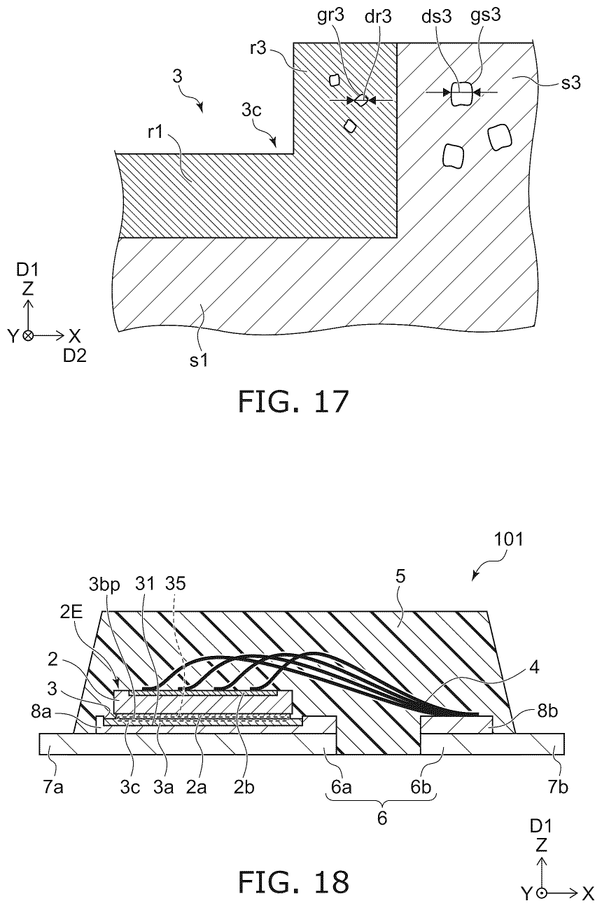

FIG. 16 and FIG. 17 are schematic cross-sectional views illustrating parts of the semiconductor device according to the first embodiment.

As shown in FIG. 16, a second mean diameter dr2 of second metal crystal grains gr2 included in the second region r2 is smaller than a second other mean diameter ds2 of second other metal crystal grains gs2 included in the second other region s2.

As shown in FIG. 17, a third mean diameter dr3 of third metal crystal grains gr3 included in the third region r3 is smaller than a third other mean diameter ds3 of third other metal crystal grains gs3 included in the third other region s3.

For example, the second region r2 may be a part of the first modified layer 3c. The third region r3 may be a part of the first modified layer 3c. FIG. 16 and FIG. 17 are enlarged views showing the metal crystal grains. In FIG. 16 and FIG. 17, the resin 5 is omitted.

FIG. 18 is a schematic cross-sectional view illustrating the semiconductor device according to the second embodiment.

As shown in FIG. 18, the semiconductor device 101 (see FIG. 3) includes the semiconductor element 2E and the base 6. The semiconductor device 101 further includes the resin 5 and the wire 4. The semiconductor element 2E includes the first electrode 2a and the semiconductor chip 2. The semiconductor element 2E further includes the second electrode 2b. At least a part of the semiconductor chip 2 is located between the first electrode 2a and the second electrode 2b. The base 6 includes the first conductive member 6a. The first conductive member 6a includes the first bonding region 3a. The first bonding region 3a may be a part of the first modified layer 3c. The first electrode 2a is located between the first bonding region 3a and the semiconductor chip 2 in the first direction D1 extending from the first bonding region 3a toward the semiconductor chip 2.

Also in the semiconductor device 101, the first bonding region 3a includes the first region r1 and the first other region s1 (see FIG. 12). The first region r1 is located between the first other region s1 and the first electrode 2a in the first direction D1. The first region r1 is in contact with the first electrode 2a. The first mean diameter dr1 of the first metal crystal grains gr1 included in the first region r1 is smaller than the first other mean diameter ds1 of the first other metal crystal grains gs1 included in the first other region s1.

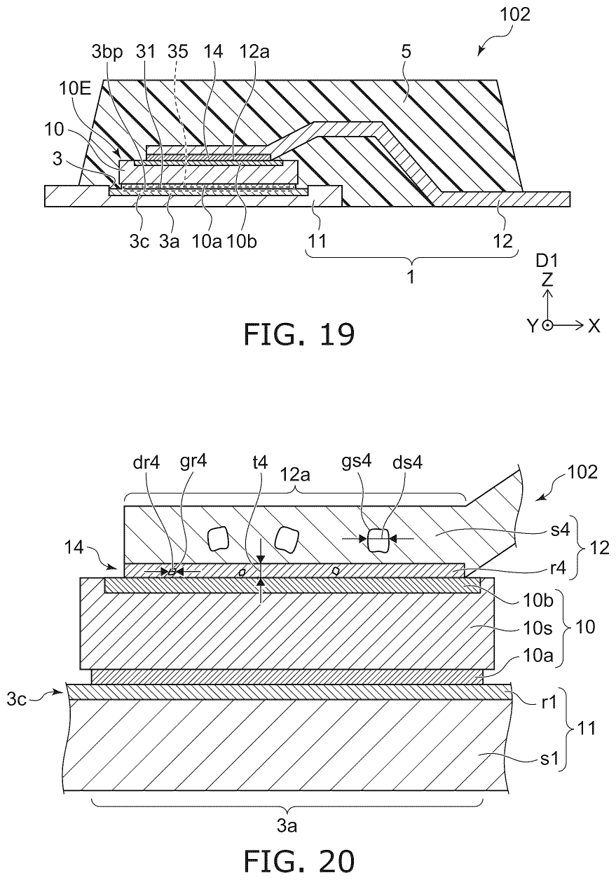

FIG. 19 is a schematic cross-sectional view illustrating the semiconductor device according to the third embodiment.

As shown in FIG. 19, the semiconductor device 102 (see FIG. 4) includes a semiconductor element 10E and the base 1. The semiconductor element 10E includes the first electrode 10a and the semiconductor chip 10. The base 1 includes the first conductive member 11. The first conductive member 11 includes the first bonding region 3a. The first bonding region 3a may be a part of the first modified layer 3c. The first electrode 10a is located between the first bonding region 3a and the semiconductor chip 10 in the first direction D1 extending from the first bonding region 3a toward the semiconductor chip 10.

As shown in FIG. 19, the semiconductor element 10E further includes the second electrode 10b. The semiconductor chip 10 is located between the first electrode 10a and the second electrode 10b. The base 1 further includes the second conductive member 12. The second conductive member 12 includes a second bonding region 12a. In the first direction D1, the second electrode 10b is located between the semiconductor chip 10 and the second bonding region 12a.

FIG. 20 is a schematic cross-sectional view illustrating a part of the semiconductor device according to the third embodiment.

FIG. 20 is an enlarged view of a part of FIG. 4 (or FIG. 19). In FIG. 20, the resin 5 is omitted. As shown in FIG. 20, in the semiconductor device 102, the second bonding region 12a includes a fourth region r4 and a fourth other region s4. The fourth region r4 is located between the second electrode 10b and the fourth other region s4 in the first direction D1. The fourth region r4 is in contact with the second electrode 10b. A fourth mean diameter dr4 of fourth metal crystal grains gr4 included in the fourth region r4 is smaller than a fourth other mean diameter ds4 of fourth other metal crystal grain gs4 included in the fourth other region s4. The fourth region r4 corresponds to at least a part of the second modified layer 14. FIG. 20 is an enlarged view showing the metal crystal grains.

A fourth thickness t4 of the fourth region r4 along the first direction D1 is, for example, more than 0.2 μm and not more than 500 μm.

Also in the semiconductor device 102, the first bonding region 3a includes the first region r1 and the first other region s1 (see FIG. 12). The first region r1 is located between the first other region s1 and the first electrode 2a in the first direction D1. The first region r1 is in contact with the first electrode 2a. The first mean diameter dr1 of the first metal crystal grains gr1 included in the first region r1 is smaller than the first other mean diameter ds1 of the first other metal crystal grains gs1 included in the first other region s1.

### Fourth Embodiment

A manufacturing method for a semiconductor device according to a fourth embodiment includes forming the recessed portion 3 in a part of the first conductive member 1a including a first metal. The bottom surface 3f of the recessed portion 3 (see FIG. 11) includes the first modified layer 3c (see FIG. 5A). The manufacturing method for the semiconductor device includes, for example, forming the first modified layer 3c in a part of the first conductive member 1a including the first metal. The forming of the first modified layer 3c may include the forming of the recessed portion 3. The manufacturing method includes placing the semiconductor element 2E including the semiconductor chip 2 and the first electrode 2a on a bottom portion 3bp so that the first electrode 2a is positioned between the bottom portion 3bp and the semiconductor chip 2 (see FIG. 5B). The manufacturing method includes bonding the first electrode 2a and the first modified layer 3c to each other by pressurizing and heating the first conductive member 1a and the semiconductor chip 2.

The manufacturing method for the semiconductor device according to the fourth embodiment may include forming the second modified layer 14 on a surface of the second conductive member 12 including a second metal. The semiconductor element 10E further includes the second electrode 10b (see FIG. 6C). The semiconductor chip 10 is located between the first electrode 10a and the second electrode 10b (see FIG. 6C). Placing of the semiconductor element 10E may include positioning the second electrode 10b between the semiconductor chip 10 and the second modified layer 14 (see FIG. 6B). The bonding includes bonding the second electrode 10b to the second modified layer 14 in addition to the bonding of the first electrode 2a and the first modified layer 3c to each other (see FIG. 6C).

The first modified layer 3c may be formed by, for example, the friction stir processing. The second modified layer 14 may be formed by, for example, the friction stir processing. The first modified layer 3c may be formed by cutting. The second modified layer 14 may be formed by cutting. Before the bonding, the first modified layer 3c may have tensile stress. Before the bonding, the second modified layer 14 may have tensile stress.

The manufacturing method may include planarizing the surface of the first electrode 2a before the placing of the semiconductor element 2E. The manufacturing method may include planarizing the surface of the first electrode 10a before the placing of the semiconductor element 10E. The bonding may include pressurizing at a temperature of not more than the recrystallization temperature of the first conductive member 1a (or the first conductive member 6a or the first conductive member 11), and thereafter, increasing the temperature to the bonding temperature.

### Fifth Embodiment

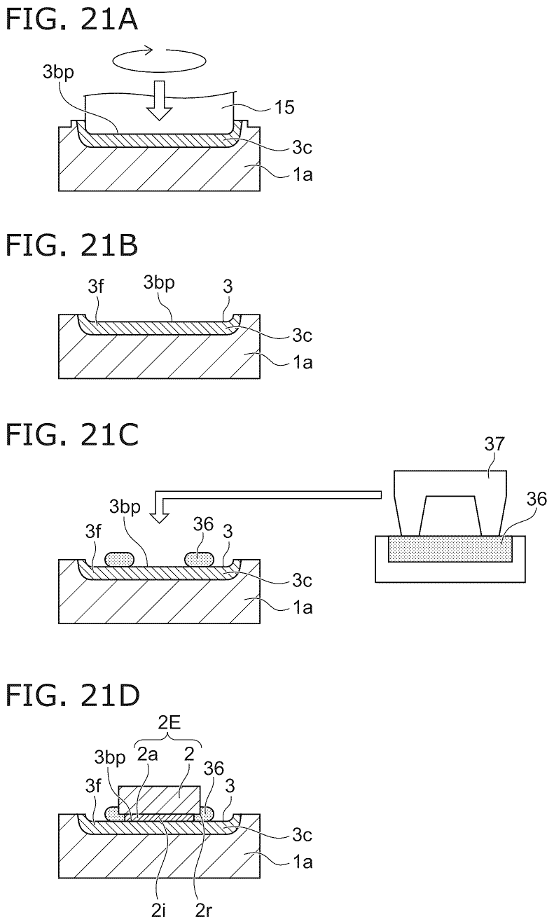

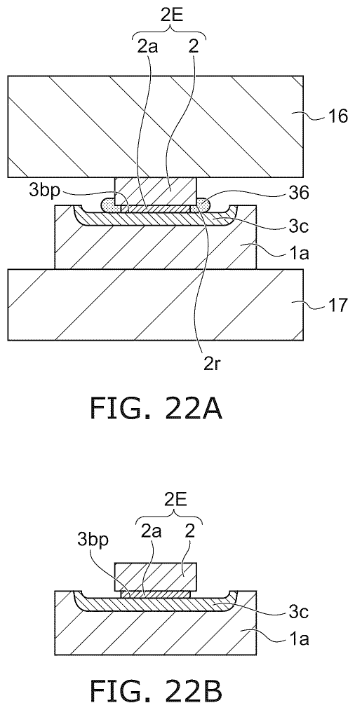

FIGS. 21A to 21D and FIGS. 22A and 22B are schematic cross-sectional views illustrating a manufacturing method for a semiconductor device according to a fifth embodiment.

As shown in FIG. 21A, also in this example, the recessed portion 3 is formed in a part of the first conductive member 1a including the first metal. As shown in FIG. 21B, the bottom portion 3bp of the recessed portion 3 includes the first modified layer 3c. For example, for example, the first modified layer 3c is formed in a part of the first conductive member 1a including the first metal. The forming of the first modified layer 3c may include the forming of the recessed portion 3.

As shown in FIG. 21C, the manufacturing method further includes supplying an organic member 36 to a part of the bottom portion 3bp before the process of placing the semiconductor element 2E. The organic member 36 is a liquid or a semisolid. For example, the organic member 36 is applied to a part of the bottom portion 3bp by a transfer tool 37.

As shown in FIG. 21D, the semiconductor element 2E is placed on the bottom portion 3bp. In the state in which the semiconductor element 2E is placed on the bottom portion 3bp, the organic member 36 is in contact with at least a part of an outer edge 2r of the semiconductor chip 2. The organic member 36 is not in contact with at least a part (inner side portion 2i) of the first electrode 2a. With the organic member 36, the position of the semiconductor element 2E is stabilized.

As shown in FIG. 22A, the semiconductor chip 2 and the first conductive member 1a are pressurized by the upper heating tool 16 and the lower heating tool 17 and bonded to each other. The bonding is performed in a state in which the organic member 36 is in contact with at least a part of the outer edge 2r. The bonding is performed at the stable position.

As shown in FIG. 22B, after the bonding, the organic member 36 is removed. For example, washing using water is performed. This enables high-strength bonding with high precision.

In the embodiment, the organic member 36 may include, for example, at least one selected from the group consisting of polyethylene glycol, polyethylene oxide, and glycerol. This facilitates stable application. The organic member 36 can be easily removed with, for example, water.

In the embodiment, the organic member 36 may satisfy at least one of a first condition, a second condition, a third condition, or a fourth condition. In the first condition, the organic member 36 is a semisolid at a temperature of not less than 20° C. and not more than 80° C. In the second condition, at least a part of the organic member 36 is a solid at a temperature of not less than 20° C. and not more than 40° C. In the third condition, the organic member 36 is a liquid at a temperature of not less than 20° C. and not more than 80° C., and the kinematic viscosity of the liquid is not less than 5 mm²/s and not more than 100 mm²/s at a temperature of not less than 20° C. and not more than 80° C. In the fourth condition, the organic member 36 is a liquid at 50° C. or more. For example, a transfer method is applied in which the temperature of the organic member 36 when attaching it to the transfer tool 37 is raised to a temperature at which the organic member 36 becomes almost liquid, and the organic member 36 is applied to a part of the bottom portion 3bp and then cooled. In this transfer method, by satisfying any of the above conditions, the amount of organic member 36 applied can be stabilized.

In the embodiment, the temperature of the organic member 36 during the supplying to the bottom portion 3bp may be, for example, not less than 50° C. and not more than 80° C.

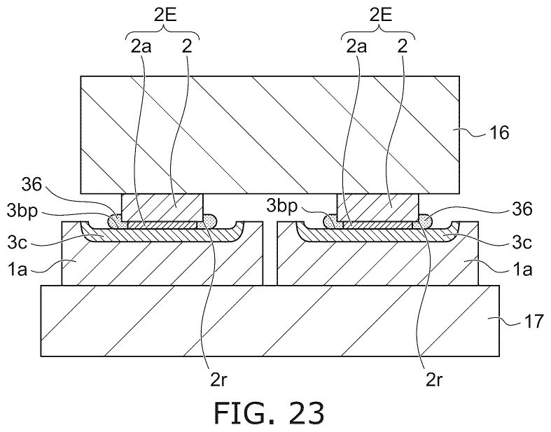

FIG. 23 is a schematic cross-sectional view illustrating the manufacturing method for the semiconductor device according to the fifth embodiment.

As shown in FIG. 23, a plurality of sets of the first conductive members 1a and the semiconductor elements 2E may be provided. Bonding may be performed for the plurality of sets at once. For example, stable position control with the organic member 36 also facilitates high-precision bonding for the plurality of sets.

The embodiments may include the following Technical proposals.

### (Technical Proposal 1)

A semiconductor device comprising:
a semiconductor element including a first electrode and a semiconductor chip; and
a base including a first conductive member including a first bonding region,
the first electrode being located between the first bonding region and the semiconductor chip in a first direction extending from the first bonding region toward the semiconductor chip,
the first bonding region including a first region and a first other region,
the first region being located between the first other region and the first electrode in the first direction,
the first region being in contact with the first electrode,
a first mean diameter of first metal crystal grains included in the first region being smaller than a first other mean diameter of first other metal crystal grains included in the first other region.

### (Technical Proposal 2)

The semiconductor device according to Technical proposal 1, wherein a first thickness of the first region along the first direction is not less than 0.2 μm and not more than 500 μm.

### (Technical Proposal 3)

The semiconductor device according to Technical proposal 1 or 2, wherein the first mean diameter is not more than 0.2 times the first other mean diameter.

### (Technical Proposal 4)

The Semiconductor Device According to any One of Technical Proposals 1 to 3, Wherein
the first mean diameter is not less than 0.01 μm and not more than 5 μm, and
the first other mean diameter is not less than 10 μm and not more than 500 μm or less.

### (Technical Proposal 5)

The Semiconductor Device According to any One of Technical Proposals 1 to 4, Wherein
the first conductive member includes a first metal element including at least one selected from the group consisting of Cu and Al, and
the first electrode includes the first metal element.

### (Technical Proposal 6)

The Semiconductor Device According to any One of Technical Proposals 1 to 5, Wherein
when the first conductive member is cut along a plane along the first direction, the first conductive member includes a recessed portion and a plurality of non-recessed portions,
a third position of the recessed portion in a second direction crossing the first direction is between a first position of one of the plurality of non-recessed portions in the second direction and a second position of another one of the plurality of non-recessed portions in the second direction, and
at least a part of the first bonding region is provided in the recessed portion.

### (Technical Proposal 7)

The Semiconductor Device According to any One of Technical Proposals 1 to 6, Wherein
the semiconductor element further includes a second electrode,
the semiconductor chip is located between the first electrode and the second electrode,
the base further includes a second conductive member including a second bonding region,
the second electrode is located between the semiconductor chip and the second bonding region in the first direction,
the second bonding region includes a fourth region and a fourth other region,
the fourth region is located between the second electrode and the fourth other region in the first direction,
the fourth region is in contact with the second electrode, and
a fourth mean diameter of fourth metal crystal grains included in the fourth region is smaller than a fourth other mean diameter of fourth other metal crystal grains included in the fourth other region.

### (Technical Proposal 8)

The Semiconductor Device According to Technical Proposal 6, Wherein
the first conductive member includes a second region and a second other region,
the second region is located between the second other region and at least a part of the first electrode in the second direction, and
a second mean diameter of second metal crystal grains included in the second region is smaller than a second other mean diameter of second other metal crystal grains included in the second other region.

### (Technical Proposal 9)

The semiconductor device according to Technical proposal 8, wherein
the first conductive member includes a third region and a third other region,
the third region is located between at least a part of the first electrode and the third other region in the second direction, and
a third mean diameter of third metal crystal grains included in the third region is smaller than a third other mean diameter of third other metal crystal grains included in the third other region.

### (Technical Proposal 10)

A Method for Manufacturing a Semiconductor Device, the Method Comprising:
forming a recessed portion in a part of a first conductive member including a first metal, a bottom portion of the recessed portion including a first modified layer;
placing a semiconductor element including a semiconductor chip and a first electrode on the bottom portion so that the first electrode is positioned between the bottom portion and the semiconductor chip; and
bonding the first electrode and the first modified layer to each other by pressurizing and heating the first conductive member and the semiconductor chip.

### (Technical Proposal 11)

The Method According to Technical Proposal 10, Further Comprising:
forming a second modified layer on a surface of a second conductive member including a second metal,
the semiconductor element further including a second electrode,
the semiconductor chip being located between the first electrode and the second electrode,
the placing of the semiconductor element including positioning the second electrode between the semiconductor chip and the second modified layer,
the bonding including bonding the second electrode to the second modified layer.

### (Technical Proposal 12)

The method according to Technical proposal 10 or 11, wherein the first modified layer is formed by a friction stir processing.

### (Technical Proposal 13)

The method according to Technical proposal 10 or 11, wherein the first modified layer is formed by cutting.

### (Technical Proposal 14)

The method according to any one of Technical proposals 10 to 13, wherein before the bonding, the first modified layer has tensile stress.

### (Technical Proposal 15)

The method according to any one of Technical proposals 10 to 14, further comprising:
planarizing a surface of the first electrode before the placing of the semiconductor element.

### (Technical Proposal 16)

The method according to any one of Technical proposals 10 to 15, wherein the bonding includes pressurizing at a temperature of not more than a recrystallization temperature of the first conductive member, and thereafter, increasing the temperature to a bonding temperature.

### (Technical Proposal 17)

The method according to any one of Technical proposals 10 to 16, further comprising:
supplying an organic member to a part of the bottom portion before the placing of the semiconductor element,
in a state in which the semiconductor element is placed on the bottom portion, the organic member being in contact with at least a part of an outer edge of the semiconductor chip, the organic member being not in contact with at least a part of the first electrode,
the bonding being performed in a state in which the organic member is in contact with the at least the part of the outer edge,
the organic member being removed after the bonding.

### (Technical Proposal 18)

The method according to technical proposal 17, wherein
at least a part of the organic member is a solid at a temperature of not less than 20° C. and not more than 40° C.,
a kinematic viscosity of the organic member in a range of not less than 20° C. and not more than 80° C. is not less than 5 mm²/s and not more than 100 mm²/s, and
the part of the organic member is a liquid at 50° C. or more.

### (Technical Proposal 19)

The method according to Technical proposal 18, wherein
a temperature of the organic member during the supplying is not less than 50° C. and not more than 80° C., and
a temperature of the organic member during the placing of the semiconductor element is not more than 40° C.

### (Technical Proposal 20)

The method according to any one of Technical proposals 17 to 19, wherein the organic member includes at least one selected from the group consisting of polyethylene glycol, polyethylene oxide, and glycerol.

According to the embodiments, a semiconductor device capable of attaining improved characteristics and a method for manufacturing the semiconductor device are provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as the bases, semiconductor chips, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices and methods for manufacturing the semiconductor devices practicable by an appropriate design modification by one skilled in the art based on the semiconductor devices and methods for manufacturing the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor element including a first electrode and a semiconductor chip; and
a base including a first conductive member including a first bonding region,
the first electrode being located between the first bonding region and the semiconductor chip in a first direction extending from the first bonding region toward the semiconductor chip,
the first bonding region including a first region and a first other region,
the first region being located between the first other region and the first electrode in the first direction,
the first region being in contact with the first electrode,
a first mean diameter of first metal crystal grains included in the first region being smaller than a first other mean diameter of first other metal crystal grains included in the first other region.

2. The semiconductor device according to claim 1, wherein a first thickness of the first region along the first direction is not less than 0.2 μm and not more than 500 μm.

3. The semiconductor device according to claim 1, wherein the first mean diameter is not more than 0.2 times the first other mean diameter.

4. The semiconductor device according to claim 1, wherein
the first mean diameter is not less than 0.01 μm and not more than 5 μm, and
the first other mean diameter is not less than 10 μm and not more than 500 μm or less.

5. The semiconductor device according to claim 1, wherein
the first conductive member includes a first metal element including at least one selected from the group consisting of Cu and Al, and
the first electrode includes the first metal element.

6. The semiconductor device according to claim 1, wherein
when the first conductive member is cut along a plane along the first direction, the first conductive member includes a recessed portion and a plurality of non-recessed portions,
a third position of the recessed portion in a second direction crossing the first direction is between a first position of one of the plurality of non-recessed portions in the second direction and a second position of another one of the plurality of non-recessed portions in the second direction, and
at least a part of the first bonding region is provided in the recessed portion.

7. The semiconductor device according to claim 1, wherein
the semiconductor element further includes a second electrode,
the semiconductor chip is located between the first electrode and the second electrode,
the base further includes a second conductive member including a second bonding region,
the second electrode is located between the semiconductor chip and the second bonding region in the first direction,
the second bonding region includes a fourth region and a fourth other region,
the fourth region is located between the second electrode and the fourth other region in the first direction,
the fourth region is in contact with the second electrode, and
a fourth mean diameter of fourth metal crystal grains included in the fourth region is smaller than a fourth other mean diameter of fourth other metal crystal grains included in the fourth other region.

8. The semiconductor device according to claim 6, wherein
the first conductive member includes a second region and a second other region,
the second region is located between the second other region and at least a part of the first electrode in the second direction, and
a second mean diameter of second metal crystal grains included in the second region is smaller than a second other mean diameter of second other metal crystal grains included in the second other region.

9. The semiconductor device according to claim 8, wherein
the first conductive member includes a third region and a third other region,
the third region is located between at least a part of the first electrode and the third other region in the second direction, and
a third mean diameter of third metal crystal grains included in the third region is smaller than a third other mean diameter of third other metal crystal grains included in the third other region.

10. A method for manufacturing a semiconductor device, the method comprising:
forming a recessed portion in a part of a first conductive member including a first metal, a bottom portion of the recessed portion including a first modified layer;
placing a semiconductor element including a semiconductor chip and a first electrode on the bottom portion so that the first electrode is positioned between the bottom portion and the semiconductor chip; and
bonding the first electrode and the first modified layer to each other by pressurizing and heating the first conductive member and the semiconductor chip.

11. The method according to claim 10, further comprising:
forming a second modified layer on a surface of a second the semiconductor element further including a second electrode,
the semiconductor chip being located between the first electrode and the second electrode,
the placing of the semiconductor element including positioning the second electrode between the semiconductor chip and the second modified layer,
the bonding including bonding the second electrode to the second modified layer.

12. The method according to claim 10, wherein the first modified layer is formed by a friction stir processing.

13. The method according to claim 10, wherein the first modified layer is formed by cutting.

14. The method according to claim 10, wherein before the bonding, the first modified layer has tensile stress.

15. The method according to claim 10, further comprising:
planarizing a surface of the first electrode before the placing of the semiconductor element.

16. The method according to claim 10, wherein the bonding includes pressurizing at a temperature of not more than a recrystallization temperature of the first conductive member, and thereafter, increasing the temperature to a bonding temperature.

17. The method according to claim 10, further comprising:
supplying an organic member to a part of the bottom portion before the placing of the semiconductor element,
in a state in which the semiconductor element is placed on the bottom portion, the organic member being in contact with at least a part of an outer edge of the semiconductor chip, the organic member being not in contact with at least a part of the first electrode,
the bonding being performed in a state in which the organic member is in contact with the at least the part of the outer edge,
the organic member being removed after the bonding.

18. The method according to claim 17, wherein
at least a part of the organic member is a solid at a temperature of not less than 20° C. and not more than 40° C.,
a kinematic viscosity of the organic member in a range of not less than 20° C. and not more than 80° C. is not less than 5 mm²/s and not more than 100 mm²/s, and
the part of the organic member is a liquid at 50° C. or more.

19. The method according to claim 18, wherein
a temperature of the organic member during the supplying is not less than 50° C. and not more than 80° C., and
a temperature of the organic member during the placing of the semiconductor element is not more than 40° C.

20. The method according to claim 17, wherein the organic member includes at least one selected from the group consisting of polyethylene glycol, polyethylene oxide, and glycerol.
